(19) United States
(12) Patent Application Publication
(10) Pub. No.: US 2009/0014065 A1
(43) Pub. Date: Jan. 15, 2009

(54) METHOD FOR THE PRODUCTION OF A TRANSPARENT CONDUCTIVE OXIDE COATING

(75) Inventors: Joachim Mueller, Fellbach (DE); Jian Liu, Grosskrotzenburg (DE); Stephan Wieder, Frankfurt (DE)

Correspondence Address: PATTERSON & SHERIDAN, L.L.P., 3040 POST OAK BOULEVARD, SUITE 1500, HOUSTON, TX, 77056, US

(73) Assignee: Applied Materials, Inc., Santa Clara, CA (US)

(21) Appl. No.: 12/171,579

(22) Filed: Jul. 11, 2008

Related U.S. Application Data
(60) Provisional application No. 60/949,396, filed on Jul. 12, 2007.

(51) Int. Cl. H01L 31/0216; C23C 14/34

(52) U.S. Cl. 136/256; 204/192.15

(57) ABSTRACT

The present invention concerns a method for the generation of a transparent conductive oxide coating (TCO layer), in particular a transparent conductive oxide coating as a transparent contact for thin section solar cells. The TCO layer consists at least of a first layer of high conductivity and a second layer of low conductivity, with the second layer generated by DC sputtering of at least one target, which contains zinc oxide and additionally aluminum, and the process atmosphere contains oxygen. Further, the present invention relates to a TCO layer as well as thin section solar cells on CIGS and CdTe basis.

### CROSS-REFERENCE TO RELATED APPLICATIONS

This application claims benefit of U.S. provisional patent application Ser. No. 60/949,396, filed Jul. 12, 2007, which is incorporated herein by reference.

### BACKGROUND OF THE INVENTION

1. Field of the Invention

The present invention concerns a method for the generation of a transparent conductive oxide coating, a transparent conductive oxide coating, and thin section solar cells having the transparent conductive oxide coating.

2. Description of the Related Art

Transparent conductive contacts are especially needed for photovoltaic applications, such as solar cells and solar modules. For this, mostly transparent conductive oxide coatings (TCO layers) are used, with indium tin oxide (ITO) having been mostly used so far. In the meanwhile, however, zinc oxide (ZnO) is enjoying great popularity for industrial use, since it is above all more economical to deposit than ITO.

It is well-known that especially a two-part structure of the zinc oxide-based TCO layer exhibits optical and electrical characteristics that are comparable to those of an ITO layer. From U.S. Pat. No. 5,078,804 is known a structure with a first ZnO layer of high electrical resistance (low conductivity) and a second ZnO layer of low electrical resistance (high conductivity), with the first ZnO layer arranged on a buffer layer covering the absorber range of a copper indium gallium diselenide (CIGS). Both ZnO layers are deposited by RF magnetron sputtering in an oxygen-argon atmosphere or a pure argon atmosphere. Further, US 2005/0109392 A1 discloses a CIGS solar cell structure, in which the buffer layer is likewise covered with a so-called intrinsic, i.e. pure ZnO layer (i-ZnO), which exhibits a high electrical resistance, and upon which is subsequently applied a ZnO layer, which is doped with aluminum and exhibits low electrical resistance. The i-ZnO-layer is deposited by RF magnetron sputtering and the ZnO layer of high conductivity is deposited by magnetron sputtering of an aluminum-doped ZnO target. This aluminum-doped ZnO target can also be DC sputtered, which substantially increases the coating rate relative to RF sputtered targets. DC sputtering is therefore used for depositing the conductive ZnO:Al layer in industrial use.

These TCO layers exhibit a typical thickness of approx. 1 μm, with the layer of low conductivity having a layer thickness in the region of approx. 50 nm. The layer of high conductivity possesses a resistivity of approx. 5×10⁻⁴ to 1×10⁻³ Ωcm. The i-ZnO-layer is typically generated by RF sputtering of an undoped ceramic ZnO target at 13.56 MHz.

The ZnO layer of low conductivity critically improves the effectiveness of the solar cell, the reason being that this layer blocks defects of the buffer layer and so increases the danger or the effect of short-circuits in the solar cell and thus increases their average efficiency as well as service life.

Disadvantageous in a TCO layer structured in this way, however, is the fact that the ZnO layer of low conductivity must be manufactured by RF sputtering. The reason is that RF sputtering permits only small coating rates compared with DC sputtering techniques. Furthermore, the RF generator as well as the necessary adaptation network are much more expensive than DC generators. In addition, the cathode and the coating installation itself must meet special requirements of RF sputtering, such as RF proofness. As a result, the coating installation has a more complicated, more complex, and more expensive structure. Finally, there is the need to keep available different target materials for the ZnO layers of low and high conductivity since only an aluminum-doped target can also be DC-sputtered, but no i-ZnO-layers can be generated therefrom. Furthermore, there is also the general necessity to keep different cathode types available.

The object of the present invention is therefore to eliminate the disadvantages specified above, i.e. to make available a procedure with which transparent conductive oxide coatings are producible, that contain ZnO layers of low conductivity which are generated with techniques other than RF deposition and in particular less complicatedly and more economically. In particular, the efficiency of a solar cell manufactured with such TCO layer is not to be less than that of a solar cell whose ZnO layer of low conductivity was manufactured by means of RF sputtering. In this connection, TCO layers as well as thin section solar cells are to be made available.

### SUMMARY OF THE INVENTION

This object is achieved by a method in accordance with claim 1, a TCO layer in accordance with claim 12 and thin section solar cells in accordance with claims 15 and 18. Advantageous embodiments of these objects are the subject of the dependent claims.

### BRIEF DESCRIPTION OF THE DRAWINGS

Further advantages of the present invention are apparent from the following description of the embodiments illustrated in the drawing. In purely schematic form,

FIG. 1 is a vacuum coating chamber for performing the inventive method.

FIG. 1a is an alternative vacuum coating chamber for performing the inventive method.

FIG. 2 shows the layer system of a CIGS solar cell manufactured with the inventive method.

FIG. 3 shows the layer system of a CdTe solar cell manufactured with the inventive method.

FIG. 4 illustrates the dependence of the resistivity on the oxygen content of the process gas atmosphere for ZnO:Al layers of low conductivity generated by MF-sputtering in accordance with the method of the invention.

### DETAILED DESCRIPTION

The inventive method is characterized by the fact that the layer of low conductivity is generated by DC sputtering of at least one zinc oxide target that additionally contains aluminum, indium, gallium or boron or a combination of these dopants, with the process atmosphere containing oxygen and aluminum being the preferred dopant. The inventors have exploited the fact that, because of the oxygen content in the process atmosphere, layers of low conductivity can also be manufactured during DC sputtering of aluminum-doped ZnO targets. An aluminum-doped ZnO layer (ZnO:Al layer) manufactured in such a way can replace the i-ZnO-layer made by RF sputtering, with the efficiency of the solar cells based on this TCO layer being the same or greater than that of solar cells with a TCO layer containing i-ZnO. Thus, solar cells of equally good or even higher efficiency can be manufactured with much improved production throughput and lower equipment costs, since DC-sputtered ZnO:Al layers can be deposited substantially faster in sufficient thickness than RF sputtered i-ZnO-layers. In particular, the RF process, which is very difficult and involves great outlay in terms of process and equipment, is avoided.

Advantageously, the oxygen content in the process atmosphere is 3% at most, as this enables ZnO:Al layers of very low conductivity to be manufactured. In particular, the oxygen content should be 2% at most and preferably 1% at most. Thus, layer resistances of 5×10⁻²Ω to approx. 10⁹Ω can be attained.

To be able to regulate this low oxygen content in the process gas more exactly, it is advantageous if the gas is not fed via a gas flow controller (MFC) of very small nominal flow rate for the pure reactive gas (oxygen) and via a further gas flow controller of large nominal flow rate for the pure noble gas, but rather if use is made of a reactive gas comprising a constant mixture of oxygen and noble gas, to which an additional proportion of pure noble gas is added. In this way, it is possible to be able to design the gas flow controller (MFC) for the reactive gas so as to be relatively large, as a result of which the low proportion of the oxygen in the process gas atmosphere can be adhered to more exactly.

If the layer of low conductivity is generated by means of pulsed DC sputtering, process stability can be improved and thus the deposition rate can be advantageously further increased, since higher power densities are possible. An increase in process stability can also be obtained by the use of medium frequency sputtering (MF-sputtering) of at least two targets. By DC sputtering in the context of the present invention is therefore meant DC sputtering, pulsed DC sputtering and MF-sputtering.

Preferably, the layer of high conductivity comprises aluminum-doped zinc oxide, which was generated by means of DC sputtering; however, other transparent oxide coatings of high conductivity, such as ITO and the like, may be used.

A ceramic target containing both zinc oxide and alumina is used advantageously as the target for DC sputtering of the second layer. Such a ZnO:Al₂O₃ target is mixed ceramic, which is typically producible by compression or sintering. Alternatively, metallic targets are also usable which consist of a Zn—Al alloy with several wt. % aluminum. Through addition of oxygen, ZnO:Al can be sputtered herefrom in the reactive process.

In a particularly preferred embodiment, both the layer of high and the layer of low conductivity are generated by sputtering of the same target material, with their being advantageously generated also from the same target and then the layer of high conductivity is generated in an inert gas atmosphere and the layer of low conductivity in an oxygen or mixed inert gas-oxygen process atmosphere.

In particular, if sputtering cathodes with smaller expansion relative to the substrate surface are to be used, it is conceivable that the substrate to be coated, which may also have a coating, executes an oscillating movement in a direction perpendicular to the deposition direction of the sputtering source. Then, the substrate surface can be repeatedly moved past the cathode by means of several oscillating motions of the substrate, and so the desired layer thickness can be regulated.

Alternatively, an in-line method may be used in which the substrate is transported past several homogeneous sputtering sources arranged one behind the other, which have the same target material. The desired layer thickness can then be regulated via the transportation speed adapted to the coating rates.

Preferably and as a step for the production of CIGS-type solar cells and modules, a substrate, in particular a glass substrate, on which is located, starting from the substrate, an essential layer structure with a layer of metal with at least one of the metals molybdenum, niobium, copper, nickel, silver and aluminum, a layer from the group copper indium diselenide, copper indium gallium diselenide, copper gallium diselenide and copper indium sulfide and a further layer from the group cadmium zinc sulfide, cadmium telluride, cadmium sulfide, zinc sulfide and zinc magnesium oxide, is coated with the layer of low conductivity and afterwards with the layer of high conductivity.

Preferably and as a step for the production of CdTe-type solar cells and modules a substrate, in particular a glass substrate, is coated with the layer of high conductivity and afterwards with the layer of low conductivity, after which, starting from the substrate, an essential layer structure with a cadmium sulfide layer, a cadmium telluride layer and a metal layer with at least one of the metals molybdenum, niobium, copper, nickel, silver and aluminum is applied.

Independent protection is sought for a transparent conductive oxide coating, in particular as a transparent contact for thin section solar cells, which comprises at least one layer of high conductivity and a layer of substantially lower conductivity, with the layer of low conductivity comprising aluminum-doped zinc oxide that was deposited in a process atmosphere containing oxygen. Preferably, this transparent conductive coating is manufactured by the inventive method described above. The layer of high conductivity advantageously comprises aluminum-doped zinc oxide that was generated by means of DC sputtering. Additionally, one or more further layers, which likewise exhibit high conductivity, can be arranged between the layers of high and low conductivity. As a result, the transparent conductive coating can be adapted even better to special conditions. For example, a defined conductivity progression can be adjusted perpendicularly to the layer sequence.

Likewise independent protection is sought for thin film solar cells that exhibit such a transparent conductive oxide coating. More precisely on the one hand for CIGS-type solar cells on a substrate, in particular a glass substrate, with an essential layer structure, starting from the substrate, in the sequence:

Metal layer comprising at least one of the metals molybdenum, niobium, copper, nickel, silver and aluminum.

Layer from the group copper indium diselenide, copper indium gallium diselenide, copper gallium diselenide and copper indium sulfide.

Layer from the group cadmium zinc sulfide, cadmium telluride, cadmium sulfide, zinc sulfide and zinc magnesium oxide.

Transparent conductive oxide coating, which has a lower layer of low conductivity and thereon an upper layer of high conductivity, and perhaps an anti-reflection layer, with the transparent conductive oxide coating structured according to the inventive oxide coating. CIGS-type therefore means in this connection that one of the absorber layers copper indium diselenide, copper indium gallium diselenide, copper gallium diselenide and copper indium sulfide is used.

On the other, for CdTe-type solar cells on a substrate, in particular a glass substrate, with an essential layer structure, starting from the substrate, in the sequence:

transparent conductive oxide coating that has a lower layer of high conductivity and thereon an upper layer of low conductivity, and a cadmium sulfide layer, a cadmium telluride layer, and a metal layer, comprising at least one of the metals molybdenum, niobium, copper, nickel, silver and aluminum, with the transparent conductive oxide coating structured according to the inventive oxide coating.

Preferably the layer of low conductivity has a thickness of 20 to 100 nm, in particular of 50 nm.

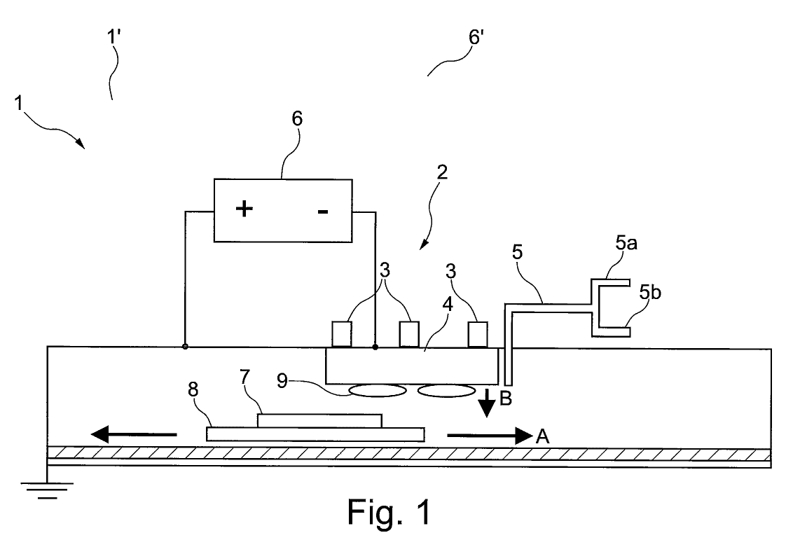

FIG. 1 shows purely schematically a vacuum treatment chamber 1 which finds use for performing the inventive method. The chamber has a of DC sputtering source 2, of which schematically only the magnet set 3 and the target 4 are shown. The target 4 is a ceramic target, which consists of zinc oxide and aluminum oxide. It is implemented as a planar target, but can also be cylindrically implemented as a component of a rotary cathode. The sputtering source 2 can be fed with process gas via a gas feed 5, on the one hand, via a first gas connection 5a either with pure oxygen or an inert gas-oxygen mixture, with an argon-oxygen mixture being preferred here and, on the other, via a second gas connection 5b with pure inert gas, with argon being preferred. The supply is regulated via respective MFC (not shown). Further, the sputtering source 2 is fed electrically via a pulsed DC voltage supply 6, although the feed could also be supplied unpulsed in the case of low power densities.

Below the sputtering source 2 is a substrate 7 located on a carrier 8, which is displaceable relative to the sputtering source 2 in a direction A perpendicular to the coating direction B. The displacement of the carrier 8 is controlled automatically. Instead of just one substrate 7, a plurality of substrates may also be accommodated on the carrier in order to make simultaneous coating possible. The substrate chamber 1 can, in displacement direction A, again be vacuum-tightly connected by air-locks (not shown) to further substrate chambers (not shown), in which coating tools are likewise arranged in order to generate further layers. It is naturally also possible to design a transport system of an in-line installation such that the substrates are carried through the installation without being accommodated in a carrier.

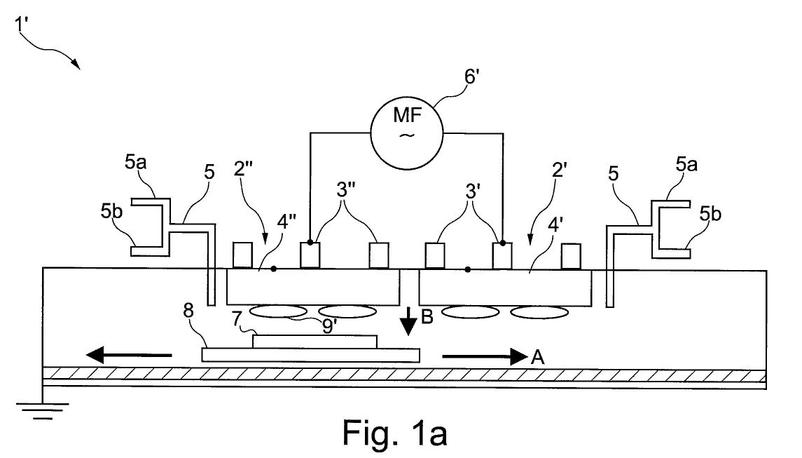

During operation of the sputtering source 2, a plasma 9 is created below the target 4, with a coating process being triggered that coats the substrate 7. The generation of the inventive transparent conductive oxide coating is now explained on the basis of the CIGS solar cell 10 schematically shown in FIG. 2.

After a molybdenum layer 12, a CIGS layer 13 and a CdTe buffer layer 14 have been applied to the glass substrate 11, the substrate 11 is transported into the vacuum treatment chamber 1 and placed beneath the sputtering source 2 (see FIG. 1). For the purpose of applying the inventive transparent conductive oxide coating, the sputtering source 2 is fed with an argon-oxygen mixture via the gas connection 5a and operated with pulsed or unpulsed DC voltage. The oxygen content is set to be no higher than 1% in terms of percent by volume. As a result, an aluminum-doped zinc oxide layer 15 of very small conductivity is deposited on the buffer layer 14. After this layer 15 has reached a thickness of 50 nm, a further aluminum-doped zinc oxide layer 16 is deposited on it, but in a pure argon atmosphere or an Ar/CO₂ atmosphere of much lower CO₂ content (typically maximum 0.1%). This layer 16 has a high conductivity and serves later as contact for the solar cell 10. Subsequently, the contact layer 16 can still be provided with an antireflection layer (not shown), as a result of which boundary face losses are reduced and the yield of the solar cell 10 increases with reference to the incident sunlight X.

The small quantity of at most 0.1% oxygen during deposition of the layer 16 of high conductivity can be necessary for the purpose of compensating that oxygen which could be lost during sputtering with pure argon in the target material. On the other hand, the inventive method requires an oxygen content of approx. 1% for the generation of the layer 15 of very low conductivity. The difference between 0.1% and 1% does not seem to be serious at first sight, yet it greatly affects the conductivity.

If, as shown in FIG. 1, the substrate 7 has a relatively large lateral expansion relative to the plasma 9, such that uniform coating cannot be guaranteed, provision is made for the substrate 7 to execute an oscillating movement over the mobile carrier 8 relative to the plasma 9 until the desired layer thickness is uniformly regulated. For this purpose, the oscillating movement of the carrier 8 can be carried out also nonuniformly or intermittently. This oscillating method is particularly suitable for smaller installations on the laboratory scale. In industrial use, an in-line method (not shown) is preferred, in which several homogeneous sputtering sources are arranged in series and in which the substrate is transported past these sources in succession. The transportation speed of the substrate is then adjusted to the coating rate and the desired coating thickness.

Instead of a DC sputtering method with a sputtering source, MF-sputtering of at least two cathodes can also be used, as shown purely schematically in FIG. 1a, with the same reference symbols designating the same parts as in FIG. 1.

The vacuum treatment chamber 1′ used for the MF-sputtering method has two homogeneous sputtering sources 2′, 2″ with magnet sets 3′, 3″ and targets 4′, 4″, which are fed with the gas feeds 5. Again, the targets 4′ are each planar ceramic targets of zinc oxide and aluminum oxide. Power is supplied by an MF-generator 6′ which provides the necessary frequencies in the range of 10 kHz to 100 kHz, preferably 40 kHz. Each of the targets 4′, 4″ works alternatingly as anode and cathode, so that process instabilities are eliminated by the fact that each target is sputtered free again in the period in which it is acting as cathode, and so the problem of a disappearing anode does not arise. With this double-magnetron sputtering method, too, the disadvantages of RF sputtering are also avoided to a large extent.

As is the case for the DC sputtering in FIG. 1, MF-sputtering can be operated both in oscillation mode and in-line mode.

While in former times an i-ZnO-layer was deposited from the undoped target by complex RF sputtering at a low deposition rate, it can be recognized that, with the inventive method, on one hand the zinc oxide layer 15 of low conductivity can be deposited much faster relatively by the less complex DC sputtering (DC sputtering, pulsed DC sputtering or MF-sputtering), so that the manufacturing process for the solar cell 10 is altogether accelerated and the cost of production falls. The installation costs are reduced in such a way, because no expensive RF generator with adaptation network and no RF capable cathodes need to be used. Moreover, the same substrate material, ZnO:Al₂O₃ and in addition also the same sputtering source 2 can be used for both coating procedures during application of the TCO layer. As a result, the TCO layer could also be produced in a single vacuum chamber 1. The material and installation costs are thus greatly reduced.

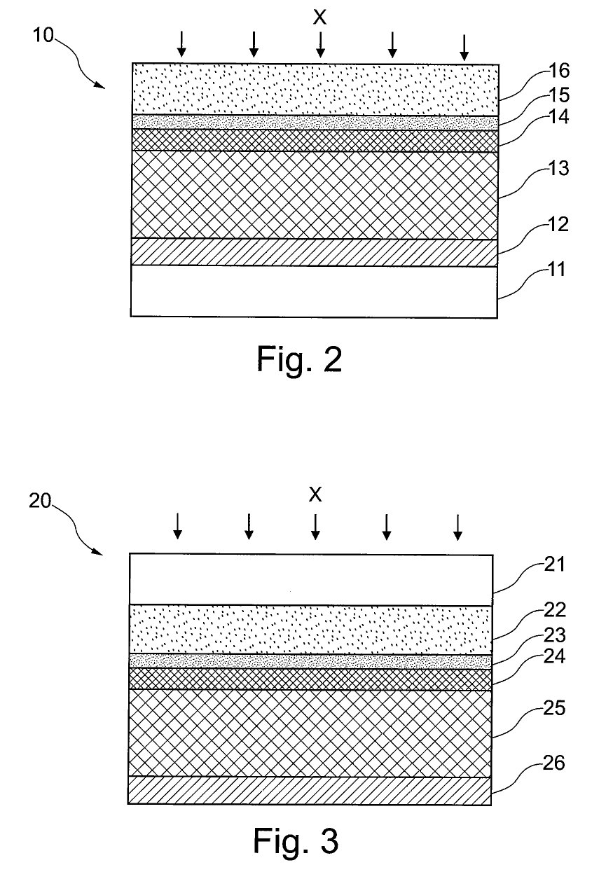

Other solar cells, too, such as CdTe-based solar cells 20, can likewise be provided with a TCO layer by means of the inventive method. For this, it is only necessary to swap the sequence of deposition of the two zinc oxide layers, as evident from FIG. 3.

An inventive CdTe solar cell 20 is therefore structured such that a ZnO:Al layer 22 of high conductivity is deposited on a glass substrate 21, followed by a ZnO:Al layer 23 of low conductivity, then a CdS buffer layer 24, a CdTe absorber layer 25 and finally a metallic contact layer 26 of molybdenum.

The solar cells 10, 20 in FIGS. 2 and 3 naturally represent only standardized solar cells 10, 20 with a typical layer structure, which can be naturally also modified. In the layer structure, further layers can be provided and, through swapping, also other layer materials. Thus, the layer of high conductivity can also be a layer other than the ZnO:Al layer 16, 22, for example an ITO layer with, especially in the case of CdTe-type solar cells, tin oxide (SnO₂) and cadmium stannate (Cd₂SnO₄) also being candidates, as well as gallium oxide (Ga₂O₃) and zinc stannate (Zn₂SnO₄). Additionally, one or more further layers of high conductivity can be provided between the layer of high 16, 22 and of low conductivity 15, 23. Finally, the absorber layer 13 of the CIGS-type solar cell can also be formed from copper indium diselenide, copper gallium diselenide and copper indium sulfide, while the buffer layer 14 can consist of cadmium zinc sulfide, cadmium telluride, cadmium sulfide, zinc sulfide (ZnS) or zinc magnesium oxide ((Zn, Mg) O).

The sole essential aspect is that the layer 15, 23 with low conductivity of the TCO layer zinc oxide comprises the aluminum-doped zinc oxide, which was generated by means of DC sputtering in an at least partial oxygen atmosphere.

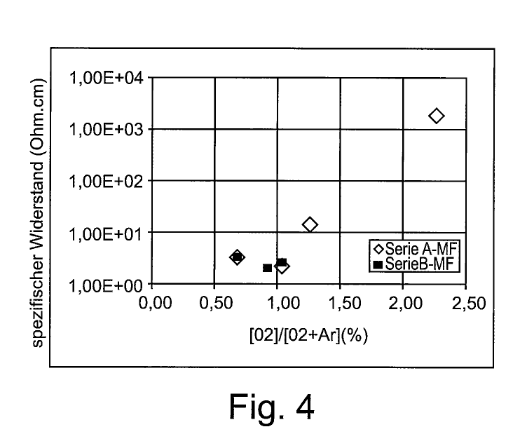

FIG. 4 shows the dependence of the resistivity on the oxygen content of the process gas atmosphere for ZnO:Al layers of low conductivity, which were manufactured in the inventive method by means of MF-sputtering. This dependence was determined for two different series that illustrate the good reproducibility of the results. The individual production parameters are summarized in Table 1.

TABLE 1

| | Power | | Gases | | | Layer properties | | | |
|---|---|---|---|---|---|---|---|---|---|
| | | Power density | | Flow of | | | | Layer | |
| | | (W per cm | | 10% O2 | O2 content: | Layer | Dynamic | resistance | Resistitivity |
| | Power | target | Ar flow | in Ar | [O2]/[Ar + O2] | thickness | rate | on glass | (Ohm |
| Sample | (kW) | length) | (sccm) | (sccm) | (%) | (nm) | (nm · m/min) | (Ohm/sq) | cm) |
| Series | 3.8 | 77.9 | 70 | 20 | 2.27 | 82 | 31.98 | 2.00E+08 | 1.64E+03 |
| A-MF | 2.3 | 47.1 | 70 | 10 | 1.27 | 36 | 14.04 | 4.00E+06 | 1.44E+01 |
| | 3.2 | 65.6 | 70 | 5 | 0.67 | 50 | 19.5 | 7.00E+05 | 3.50E+00 |
| | 3.2 | 65.6 | 70 | 8 | 1.04 | 49 | 19.11 | 4.60E+05 | 2.25E+00 |
| Series | 3.2 | 65.6 | 70 | 8 | 1.04 | 48 | 18.7 | 5.50E+05 | 2.64E+00 |
| B-MF | 1.6 | 32.8 | 70 | 5 | 0.67 | 50 | 6.5 | 7.00E+05 | 3.50E+00 |
| | 3.2 | 65.6 | 100 | 10 | 0.92 | 61 | 23.8 | 3.40E+05 | 2.07E+00 |

From the above mentioned deliberations, it is clear that, with the aid of the present invention, TCO layers that contain a zinc oxide layer 15, 23 of low conductivity can be realized in a particularly simple and cost-effective way. As a result, thin-section solar cells 10, 20, in which these TCO layers can be used as transparent electrically conductive contacts, can be generated much more cost effectively. These TCO layers can also be used in other devices, however.

While the foregoing is directed to embodiments of the invention, other and further embodiments of the invention may be devised without departing from the basic scope thereof, and the scope thereof is determined by the claims that follow.

What is claimed is:

1. A method for generating a transparent conductive oxide contact layer on a substrate for thin-section solar cells, comprising:
generating a first layer by means of DC sputtering, the first layer comprising aluminum-doped zinc oxide; and
generating a second layer by DC sputtering at least one target comprising zinc oxide and at least one of aluminum, indium, gallium, boron, and combinations thereof in a process atmosphere comprising oxygen.

2. The method of claim 1, wherein the oxygen content in the process atmosphere is between about 3% and about 0.2%.

3. The method of claim 1, wherein the process atmosphere further comprises an inert gas.

4. The method of claim 1, wherein the second layer is generated by pulsed DC sputtering.

5. The method according to claim 1, wherein the second layer is generated by MF sputtering from a double cathode.

6. The method of claim 1, wherein a ceramic ZnO:Al₂O₃ target serves as the target for sputtering the second layer.

7. The method of claim 1, wherein both the first and the second layer are generated by sputtering of the same target.

8. The method of claim 1, further comprising oscillating the substrate on which the transparent conductive oxide coating is to be deposited in a direction perpendicular to the deposition direction of a sputtering source.

9. The method of claim 1, further comprising transporting the substrate past several sputtering sources to generate a necessary layer thickness in in-line operation.

10. The method of claim 1, further comprising:
applying a layer structure on the substrate by a process comprising:
applying a metal layer on the substrate, the metal layer comprising at least one of molybdenum, niobium, copper, nickel, silver and aluminum;
applying an absorber layer on the metal layer, the absorber layer comprising at least one of copper indium diselenide, copper indium gallium diselenide, copper gallium diselenide and copper indium sulfide;
applying a buffer layer on the absorber layer, the buffer layer comprising at least one of cadmium zinc sulfide, cadmium telluride, cadmium sulfide, zinc sulfide, and zinc magnesium oxide;
coating the buffer layer with the second layer of low conductivity; and
coating the second layer with the first layer of high conductivity.

11. The method of claim 1, further comprising:
coating the first layer of high conductivity on the substrate;
coating the second layer of low conductivity on the first layer;
applying a cadmium sulfide layer onto the second layer;
applying a cadmium telluride layer onto the cadmium sulfide layer; and
applying a metal layer with at least one of the metals molybdenum, niobium, copper, nickel, silver and aluminum, onto the cadmium sulfide layer.

12. A transparent conductive oxide contact layer on a substrate for thin-section solar cells, comprising:
a first layer of high conductivity; and
a second layer of a much lower conductivity, where the second layer comprises aluminum-doped zinc oxide deposited in a process atmosphere containing oxygen.

13. The oxide contact layer of claim 12, wherein the second layer has a layer thickness in the range 20 nm to 100 nm.

14. The oxide layer of claim 12, wherein between the first and the second layer are arranged further layers, which likewise exhibit high conductivity.

15. A thin section solar cell on a substrate, comprising
a layer structure on the substrate, the layer structure comprising:
a metal layer comprising at least one of the metals molybdenum, niobium, copper, nickel, silver and aluminum;
an absorber layer on the metal layer, the absorber layer comprising at least one of copper indium diselenide, copper indium gallium diselenide, copper gallium diselenide and copper indium sulfide;
a buffer layer on the absorber layer, the buffer layer comprising at least one of cadmium zinc sulfide, cadmium telluride, cadmium sulfide, zinc sulfide and zinc magnesium oxide;
a transparent conductive oxide layer comprising:
a low conductivity layer on the layer buffer layer, the low conductivity layer comprising aluminum-doped zinc oxide deposited in a process atmosphere containing oxygen; and
a high conductivity layer on the transparent conductive oxide layer.

16. The thin solar section cell of claim 15, further comprising:
an anti-reflection layer on the high conductivity layer.

17. The thin section solar cell of claim 15, wherein the low conductivity layer has a thickness of 20 to 100 nm.

18. A thin section solar cell on a substrate, comprising:
a layer structure on the substrate, the layer structure comprising:
a transparent conductive oxide coating having a high conductivity layer on the substrate and a low conductivity layer on the high conductivity layer, the low conductivity layer comprising aluminum-doped zinc oxide deposited in a process atmosphere containing oxygen;
a cadmium sulfide layer on the low conductivity layer;
a cadmium telluride layer on the cadmium sulfide layer; and
a metal layer on the cadmium telluride layer, the metal layer comprising at least one of molybdenum, niobium, copper, nickel, silver and aluminum.

19. The thin section solar cell of claim 18, wherein the low conductivity layer has a thickness of 20 to 100 nm.
